(19) United States
(12) Patent Application Publication
(10) Pub. No.: US 2025/0120012 A1
(43) Pub. Date: Apr. 10, 2025

(54) STRETCHABLE DEVICE

(71) Applicant: Murata Manufacturing Co., Ltd., Nagaokakyo-shi (JP)

(72) Inventor: Takayoshi OBATA, Nagaokakyo-shi (JP)

(21) Appl. No.: 18/983,657

(22) Filed: Dec. 17, 2024

Related U.S. Application Data
(63) Continuation of application No. PCT/JP2023/022959, filed on Jun. 21, 2023.

(30) Foreign Application Priority Data
Jun. 30, 2022 (JP) 2022-106362

(51) Int. Cl. H05K 1/02; H05K 1/18

(52) U.S. Cl. CPC H05K 1/0283; H05K 1/181; H05K 2201/0129; H05K 2201/0314; H05K 2201/032

(57) ABSTRACT

A stretchable device that includes: a stretchable substrate having a main surface; an electronic component on the main surface of the stretchable substrate; a first stretchable wiring connected to the electronic component; and a second stretchable wiring connected to the first stretchable wiring. A first end portion in an extending direction of the first stretchable wiring is connected to the electronic component, and a second end portion in the extending direction of the first stretchable wiring is connected to a third end portion in the extending direction of the second stretchable wiring.

### CROSS REFERENCE TO RELATED APPLICATIONS

The present application is a continuation of International application No. PCT/JP2023/022959, filed Jun. 21, 2023, which claims priority to Japanese Patent Application No. 2022-106362, filed Jun. 30, 2022, the entire contents of each of which are incorporated herein by reference.

### TECHNICAL FIELD

The present disclosure relates to a stretchable device.

### BACKGROUND ART

Conventionally, as a stretchable device, there is one described in WO 2009/081929 A (Patent Document 1). The stretchable device includes an insulating substrate, a first conductor having a land provided on the insulating substrate, a second conductor provided on the land, solder individually provided on the second conductor, and an electronic component having an electrode portion independently in contact with the solder.
Patent Document 1: WO 2009/081929 A

### SUMMARY OF THE DISCLOSURE

In the device of the conventional technique, an end portion of the electronic component is arranged so as to overlap an overlapping region of the first conductor and the second conductor. Solder provided on the second conductor is also arranged so as to overlap the overlapping region.

By evaluation of the device of the conventional technique having the above structure, it has been found that mechanical strength is low in the device of the conventional technique. Based on detailed studies, it has been found that in a case where a stretchable substrate having stretchability is used as a substrate, stress at the time of stretching may be most concentrated in the vicinity of an interface between a connection member such as solder and wiring. For this reason, it has been found that, in the device of the conventional technique, disconnection of a wiring, interfacial delamination between a substrate and a wiring, and the like may occur.

In view of the above, an object of the present disclosure is to provide a stretchable device in which mechanical strength can be improved.

In order to achieve the above object, a stretchable device according to an aspect of the present disclosure includes: a stretchable substrate having a main surface; an electronic component on the main surface of the stretchable substrate; a first stretchable wiring connected to the electronic component; and a second stretchable wiring connected to the first stretchable wiring, in which a first end portion in an extending direction of the first stretchable wiring is connected to the electronic component, and a second end portion in the extending direction of the first stretchable wiring is connected to a third end portion in the extending direction of the second stretchable wiring.

According to the stretchable device according to one aspect of the present disclosure, mechanical strength can be improved.

### BRIEF EXPLANATION OF THE DRAWINGS

FIG. 1 is a schematic perspective view illustrating a part of a stretchable device according to a first embodiment of the present disclosure.

FIG. 2 is a sectional view taken along II-II of FIG. 1.

FIG. 3 is a schematic perspective view illustrating the stretchable device according to a second embodiment of the present disclosure.

FIG. 4 is a schematic plan view illustrating a part of the stretchable device according to the second embodiment of the present disclosure.

FIG. 5 is a graph illustrating a relationship between stress and elongation of a stretchable wiring according to an example.

FIG. 6 is a graph illustrating thickness dependency of a relationship between an expansion and contraction rate and a resistance value of the stretchable wiring according to the example.

FIG. 7 is a schematic perspective view illustrating a part of the stretchable device according to the example.

FIG. 8A is a diagram illustrating an application shape of paste.

FIG. 8B is a diagram illustrating an application shape of paste.

### DESCRIPTION OF THE PREFERRED EMBODIMENTS

Hereinafter, embodiments of the present disclosure will be described in detail with reference to the drawings. In each embodiment, a difference from description before the embodiment will be mainly described. Particularly, similar functions and effects achieved by similar configurations will not be mentioned sequentially for each of the embodiments. Among constituent elements in the embodiments below, a constituent element not described in an independent claim will be described as an optional constituent element. Further, sizes and ratios of sizes of constituent elements illustrated in the drawings are not necessarily strict. Further, in the drawings, substantially the same configurations are denoted by the same reference symbols, and redundant description may be omitted or simplified.

### First Embodiment

### (Overall Configuration)

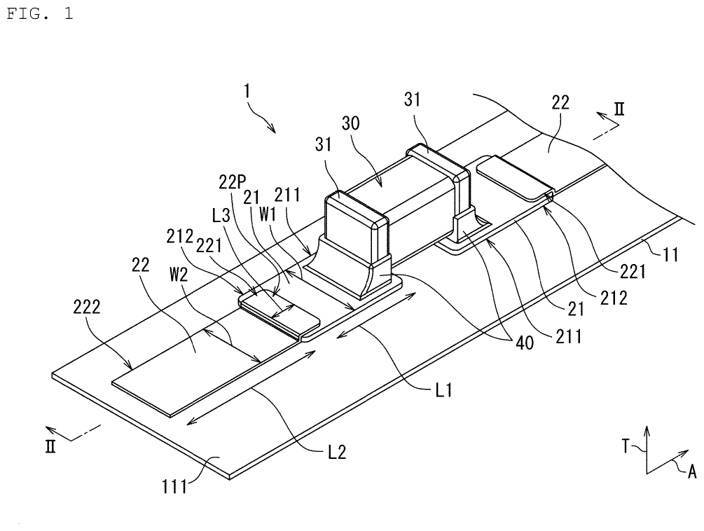

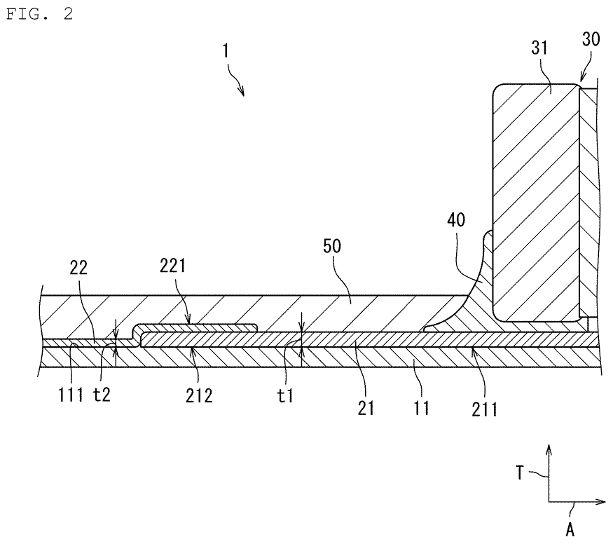

An overall configuration of a stretchable device 1 according to a first embodiment will be described with reference to FIGS. 1 and 2. FIG. 1 is a schematic perspective view illustrating a part of the stretchable device 1. FIG. 2 is a sectional view taken along II-II of FIG. 1. Note that, in FIG. 1, description of a covering layer is omitted.

In the drawings of the present description, a thickness direction of a stretchable substrate is indicated by an arrow T. The “direction orthogonal to a main surface of a stretchable substrate” described in the claims corresponds to the T direction. Further, in the present description, a direction from a main surface of a stretchable substrate on which a stretchable wiring is not provided to a main surface of the stretchable substrate on which a stretchable wiring is provided in the T direction is defined as an upper side.

The stretchable device 1 includes a stretchable substrate 11 having a main surface 111, an electronic component 30 provided on the main surface 111 of the stretchable substrate 11, a first stretchable wiring 21 connected to the electronic component 30, a second stretchable wiring 22 connected to the first stretchable wiring 21, and a covering layer 50 provided so as to cover the first stretchable wiring 21 and the second stretchable wiring 22. The stretchable device 1 is, for example, attached to a living body and used to measure a biological signal.

Here, “on the main surface of the stretchable substrate” refers to not an absolute direction such as a vertically upward direction defined in the direction of gravity but a direction toward the outside between the outside and the inside of the stretchable substrate with a main surface of the stretchable substrate as a boundary. Therefore, “on the main surface of the stretchable substrate” is a relative direction determined by an orientation of a main surface of the stretchable substrate. Further, “on” a certain element includes not only a position immediately above and in contact with the element (on) but also an upper position away from the element, that is, an upper position with another object on the element interposed between them or an upper position with a space between them (above).

The stretchable substrate 11 is a sheet-like or film-like substrate made from a stretchable resin material. Examples of the resin material include thermoplastic polyurethane (TPU). Thickness of the stretchable substrate 11 is not particularly limited, but is preferably 1 mm or less, more preferably 100 μm or less, still more preferably 50 μm or less from the viewpoint of preventing stretching of a surface of a living body from being impaired when the stretchable substrate 11 is attached to the living body. Further, thickness of the stretchable substrate 11 is preferably 1 μm or more. A shape of the stretchable substrate 11 is not particularly limited. In this embodiment, the stretchable substrate 11 has a shape extending in one direction A as viewed in the thickness direction T.

The electronic component 30 is, for example, a capacitor component, an inductor component, or an IC (semiconductor integrated circuit). A type of the electronic component 30 is not particularly limited. A shape of the electronic component 30 is not particularly limited, but is a rectangular parallelepiped shape in this embodiment. The electronic component 30 is arranged such that a longitudinal direction is parallel to an extending direction (hereinafter referred to as “A direction”) of the stretchable substrate 11. External electrodes 31 are provided in both end portions in the A direction of the electronic component 30.

The first stretchable wiring 21 is a member having a function of reducing stress applied to the stretchable device 1. The first stretchable wiring 21 is formed of a conductive material having stretchability. As the conductive material, for example, metal foil of silver, copper, nickel or the like may be used, or a mixture of metal powder of silver, copper, nickel or the like and elastomeric resin such as epoxy resin, urethane resin, acrylic resin, and silicone resin may be used. The first stretchable wiring 21 preferably has Young's modulus larger than that of the second stretchable wiring 22. A shape of the first stretchable wiring 21 is not particularly limited, but in this embodiment, is a shape of extending in one direction. Specifically, an extending direction of the first stretchable wiring 21 is parallel to the A direction.

A first end portion 211 in the extending direction of the first stretchable wiring 21 is connected to the electronic component 30. Specifically, the first end portion 211 in the extending direction of the first stretchable wiring 21 is connected to the external electrode 31 on one side of the electronic component 30 with a connection member 40 interposed therebetween. The connection member 40 is, for example, solder, a conductive adhesive, or the like.

A length L1 in the extending direction of the first stretchable wiring 21 is preferably, for example, 0.2 mm to 5 mm. In the present description, the length L1 does not include an overlapping portion with the second stretchable wiring 22. A width W1 in a direction orthogonal to the extending direction of the first stretchable wiring 21 is preferably, for example, 0.2 mm to 3.2 mm. Thickness t1 in the T direction of the first stretchable wiring 21 is preferably, for example, 10 μm to 30 μm.

The second stretchable wiring 22 is a wiring mainly responsible for transmission and receiving of a biological signal and the like. The second stretchable wiring 22 is formed of a conductive material having stretchability. As the conductive material, for example, metal foil of silver, copper, nickel or the like may be used, or a mixture of metal powder of silver, copper, nickel or the like and elastomeric resin such as epoxy resin, urethane resin, acrylic resin, and silicone resin may be used. A shape of the second stretchable wiring 22 is not particularly limited, but in this embodiment, is a shape of extending in one direction. Specifically, an extending direction of the second stretchable wiring 22 is parallel to the A direction. That is, an extending direction of the second stretchable wiring 22 is parallel to the extending direction of the first stretchable wiring 21. In the present application, the term “parallel” is not limited to a strict parallel relationship, and includes a substantial parallel relationship in consideration of a realistic variation range.

A first end portion 221 in the extending direction of the second stretchable wiring 22 is connected to a second end portion 212 in the extending direction of the first stretchable wiring 21. Specifically, the first end portion 221 in the extending direction of the second stretchable wiring 22 is laminated on the second end portion 212 in the extending direction of the first stretchable wiring 21 and connected to the second end portion 212 in the extending direction of the first stretchable wiring 21. However, the present disclosure is not limited to this, and the second end portion 212 in the extending direction of the first stretchable wiring 21 may be laminated on the first end portion 221 in the extending direction of the second stretchable wiring 22 and connected to the first end portion 221 in the extending direction of the second stretchable wiring 22. A length L3 in the A direction of a portion (overlapping portion) 22P overlapping the first stretchable wiring 21 of the second stretchable wiring 22 is preferably, for example, 0.1 mm to 1 mm.

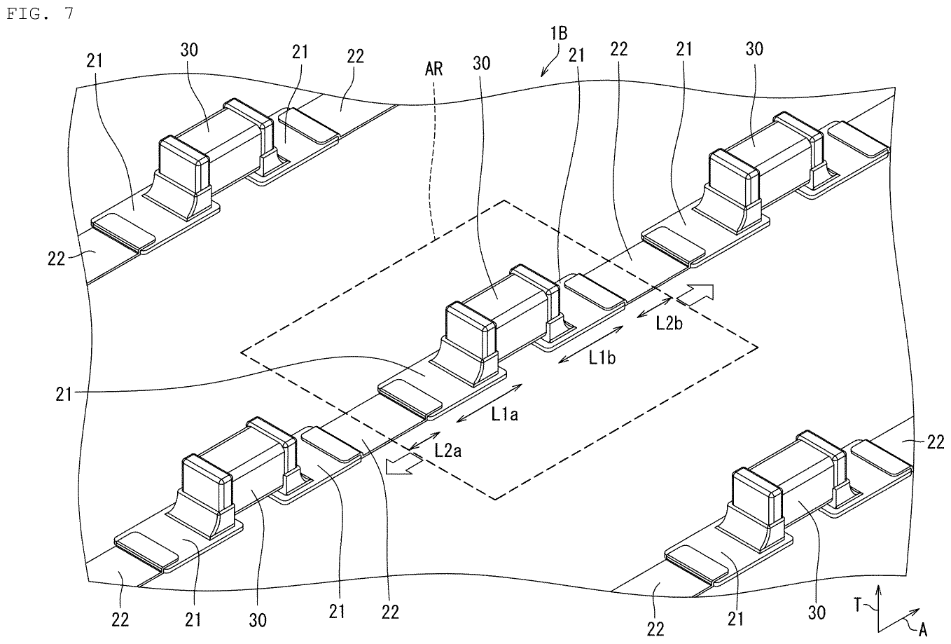

A length L2 in the extending direction of the second stretchable wiring 22 is preferably, for example, three times or more the length L1. In the present description, the length L2 does not include an overlapping portion with the first stretchable wiring 21. Further, as illustrated in FIG. 7 to be described later, in a case where there are a plurality of the electronic components 30 and one of the second stretchable wiring 22 is connected to a plurality of the electronic components 30, L2 is a length to a midpoint between the electronic components 30 adjacent to each other in the extending direction of the second stretchable wiring 22. A width W2 in a direction orthogonal to the extending direction of the second stretchable wiring 22 is preferably, for example, 0.2 mm to 3.2 mm. Thickness t2 in the T direction of the second stretchable wiring 22 is preferably, for example, 10 μm to 30 μm.

In this embodiment, there are two sets of stretchable wirings each including the first stretchable wiring 21 connected to the external electrode 31 of the electronic component 30 and the second stretchable wiring 22 connected to the first stretchable wiring 21, corresponding to each of two of the external electrodes 31 provided at both end portions in the A direction of the electronic component 30.

The covering layer 50 protects the first stretchable wiring 21 and the second stretchable wiring 22 from an external environment. The covering layer 50 is, for example, potting resin. The covering layer 50 is preferably a stretchable resin material, and is preferably, for example, ionomer resin, polyester resin, styrene resin, olefin resin, epoxy resin, urethane resin, acrylic resin, or silicone resin, and more preferably urethane resin. Note that the covering layer 50 does not need to be provided, but preferably covers at least a connection portion between the first stretchable wiring 21 and the electronic component 30.

According to the stretchable device 1, since the first end portion 211 in the extending direction of the first stretchable wiring 21 is connected to the electronic component 30 and the second end portion 212 in the extending direction of the first stretchable wiring 21 is connected to the first end portion 221 in the extending direction of the second stretchable wiring 22, an end portion of the electronic component 30 does not overlap the connection portion between the first stretchable wiring 21 and the second stretchable wiring 22 when viewed from a direction orthogonal to the main surface 111 of the stretchable substrate 11. Furthermore, the connection member 40 that connects the electronic component 30 and the first stretchable wiring 21 can also be arranged so as not to overlap the connection portion between the first stretchable wiring 21 and the second stretchable wiring 22. By the above, different members can be arranged stepwise from an end portion of the electronic component 30 toward the second stretchable wiring 22. As a result, stress that may concentrate on the connection portion between the electronic component 30 and the first stretchable wiring 21 can be dispersed from the end portion of the electronic component 30 toward the second stretchable wiring 22, and concentration of the stress can be reduced. As a result, mechanical strength of the stretchable device 1 can be improved.

### (Tensile Load Ratio)

In the stretchable device 1, it is preferable to satisfy the following Formulas (1) and (2). Note that, in description below, it is assumed that an expansion and contraction direction is parallel to the A direction.

$$σ 1 \leq allowable stress σ {1}_{max} of first stretchable wiring \qquad ( 1 )$$

$$σ 2 \leq allowable stress σ {2}_{max} of second stretchable wiring \qquad ( 2 )$$

$$where$$

$$σ 1 = ( δ \times E 1 \times S 2 \times E 2 ) / ( L 1 \times S 2 \times E 2 + L 2 \times S 1 \times E 1 ) \qquad ( 3 )$$

$$σ 2 = ( δ \times E 1 \times S 1 \times E 2 ) / ( L 1 \times S 2 \times E 2 + L 2 \times S 1 \times E 1 ) \qquad ( 4 )$$

δ: Overall displacement amount of the first stretchable wiring 21 and the second stretchable wiring 22
L1: Length of the first stretchable wiring 21 in the expansion and contraction direction (A direction)
L2: Length of the second stretchable wiring 22 in the expansion and contraction direction
S1: Sectional area of the first stretchable wiring 21 in a section orthogonal to the expansion and contraction direction (the thickness t1×the width W1 of the first stretchable wiring 21)
S2: Sectional area of the second stretchable wiring 22 in a section orthogonal to the expansion and contraction direction (the thickness t2×the width W2 of the second stretchable wiring 22)
E1: Elastic modulus of the first stretchable wiring
E2: Elastic modulus of the second stretchable wiring 22

The above σ1 means a tensile load acting on the first stretchable wiring 21 when the displacement amount δ is applied to the entire first stretchable wiring 21 and second stretchable wiring 22. The above σ2 means a tensile load acting on the second stretchable wiring 22 when the displacement amount δ is applied to the entire first stretchable wiring 21 and second stretchable wiring 22. That is, satisfying the above Formulas (1) and (2) means that each of a first tensile load ratio and a second tensile load ratio calculated by a formula below is one or less.

$$First tensile load ratio = ( tensile load σ 1 acting on first stretchable \\ wiring 22 ) / ( allowable stress σ {2}_{max} of second stretchable wiring 22 )$$

$$Second tensile load ratio = ( tensile load σ 2 acting on second stretchable \\ wiring 22 ) / ( allowable stress σ {2}_{max} of second stretchable wiring 22 )$$

Here, derivation of Formulas (3) and (4) above, which are calculation formulas of the tensile load σ1 and the tensile load σ2, will be described. When the displacement amount δ is applied to the entire first stretchable wiring 21 and second stretchable wiring 22, a load F applied to the first stretchable wiring 21 and the second stretchable wiring 22 is expressed by a formula below.

$$F = δ / [ \{ L 1 / ( E 1 \times S 1 ) \} + \{ L 2 / ( E 2 \times S 2 ) \} ]$$

The tensile load σ1 and the tensile load σ2 are derived from a formula below using the load F.

$$σ 1 = F / S 1 = ( δ / S 1 ) \times ( \{ E 1 \times S 1 \times E 2 \times S 2 ) / ( L 1 \times S 2 \times E 2 + L 2 \times S 1 \times E 1 ) \} = ( δ \times E 1 \times S 2 \times E 2 ) / ( L 1 \times S 2 \times E 2 + L 2 \times S 1 \times E 1 )$$

$$σ 2 = F / S 2 = ( δ / S 2 ) \times \{ ( E 1 \times S 1 \times E 2 \times S 2 ) / ( L 1 \times S 2 \times E 2 + L 2 \times S 1 \times E 1 ) \} = ( δ \times E 1 \times S 1 \times E 2 ) / ( L 1 \times S 2 \times E 2 + L 2 \times S 1 \times E 1 )$$

As can be seen from Formulas (3) and (4) above, the tensile load σ1 and the tensile load σ2 can be adjusted by adjusting the elastic moduli E1 and E2, the lengths L1 and L2 in the expansion and contraction direction, the sectional areas S1 and S2, and the length L3 of a portion where the first stretchable wiring 21 and the second stretchable wiring 22 overlap each other, of the first stretchable wiring 21 and the second stretchable wiring 22. Note that when a length in the expansion and contraction direction of each member of the first stretchable wiring 21 and the second stretchable wiring 22 is a predetermined length, the lengths L1 and L2 in the expansion and contraction direction of the first stretchable wiring 21 and the second stretchable wiring 22 can be adjusted by adjusting a length of the portion where the first stretchable wiring 21 and the second stretchable wiring 22 overlap each other.

Note that calculation of the tensile load σ1 and calculation of the tensile load σ2 are described for one of two sets of stretchable wirings, but the same applies to the other set. That is, δ, L1, L2, S1, S2, E1, and E2 can be defined for each of two sets of stretchable wirings.

The allowable stress σ1ₘₐₓ of the first stretchable wiring 21 in Formula (1) above is stress at maximum elongation of the first stretchable wiring 21. The allowable stress σ1ₘₐₓ of the first stretchable wiring 21 only needs to be, for example, stress when the first stretchable wiring 21 is broken by measuring a relationship (stress-strain diagram) between elongation and stress of the first stretchable wiring 21 after the first stretchable wiring 21 is cut out by a predetermined length in the extending direction. The allowable stress σ2ₘₐₓ of the second stretchable wiring 22 in Formula (2) above is stress at maximum elongation of the second stretchable wiring 22. The allowable stress °2ₘₐₓ of the second stretchable wiring 22 only needs to be, for example, stress when the second stretchable wiring 22 is broken by measuring a relationship between elongation and stress of the second stretchable wiring 22 after the second stretchable wiring 22 is cut out by a predetermined length in the extending direction.

That the first tensile load ratio is one or less means that the tensile load σ1 acting on the first stretchable wiring 21 is smaller than the allowable stress σ1ₘₐₓ of the first stretchable wiring 21. That is, it means that, with a selected configuration of the first stretchable wiring 21, the first stretchable wiring 21 is not broken and mechanical strength of the first stretchable wiring 21 is sufficient. Similarly, that the second tensile load ratio is one or less means that the tensile load σ2 acting on the second stretchable wiring 22 is smaller than the allowable stress σ2ₘₐₓ of the second stretchable wiring 22. That is, it means that, with a selected configuration of the second stretchable wiring 22, the second stretchable wiring 22 is not broken and mechanical strength of the second stretchable wiring 22 is sufficient.

Since each of the first tensile load ratio and the second tensile load ratio is one or less as Formulas (1) and (2) above are satisfied, it is possible to suppress breakage of each of the first stretchable wiring 21 and the second stretchable wiring 22. Further, by satisfying Formulas (1) and (2) above, it is possible to determine a shape and a material of the first stretchable wiring 21 and the second stretchable wiring 22 corresponding to the displacement amount δ. For this reason, the displacement amount δ is in a range in which the stretchable device 1 is not broken.

More preferably, a formula below is further satisfied.

$$σ 1 \leq 0.8 \times allowable stress σ {1}_{max} of first stretchable wiring 21 \\ σ 2 \leq 0.8 \times allowable stress σ {2}_{max} of second stretchable wiring 22$$

According to this configuration, breakage of the first stretchable wiring 21 and the second stretchable wiring 22 can be more reliably suppressed.

Further, and more preferably, a formula below is further satisfied.

$$σ 1 \leq 0.5 \times allowable stress σ {1}_{max} of first stretchable wiring 21 \\ σ 2 \leq 0.5 \times allowable stress σ {2}_{max} of second stretchable wiring 22$$

According to this configuration, breakage of the first stretchable wiring 21 and the second stretchable wiring 22 can be further and more reliably suppressed.

### (Other Preferable Configurations)

Preferably, the connection member 40 that connects the electronic component 30 and the first stretchable wiring 21 is further included, and the connection member 40 does not overlap the first end portion 221 in the extending direction of the second stretchable wiring 22 as viewed from a direction (the T direction) orthogonal to the main surface 111 of the stretchable substrate 11. According to this configuration, for example, in a case where the connection member 40 is solder, it is possible to suppress the second stretchable wiring 22 from being thermally affected at the time of forming the connection member 40.

Preferably, solder leaching resistance of the first stretchable wiring 21 is higher than solder leaching resistance of the second stretchable wiring 22. Solder leaching is a phenomenon in which metal or the like in a stretchable wiring melts into solder and volume of the stretchable wiring decreases. According to this configuration, in a case where the connection member 40 is solder, connection reliability between the first stretchable wiring 21 and the connection member 40 can be improved.

As an example of a method for evaluating solder leaching resistance, for example, a stretchable wiring is immersed in molten solder, and a graph showing a relationship between immersion time and an amount of metal in the molten stretchable wiring is created. Then, it can be evaluated that solder leaching is more likely to occur, that is, solder leaching resistance is lower as a slope of the graph is larger.

Preferably, solubility (chemical attack) in resin of the first stretchable wiring 21 is smaller than solubility (chemical attack) in the resin of the second stretchable wiring 22. According to this configuration, also in a case where the covering layer 50 is, for example, potting resin and covers at least the connection portion between the electronic component 30 and the first stretchable wiring 21, a material of the first stretchable wiring 21 can be prevented from being dissolved in the covering layer 50.

Evaluation of solubility in resin of a stretchable wiring can be performed based on, for example, JIS K 7114:2001 (ISO 175:1999). In this test method, a whole test piece is immersed in test liquid at specified temperature and for specified time. Mass of the test piece is measured before immersion and after being taken out of the test liquid and dried as necessary. It can be evaluated that the larger the mass change, the larger the solubility in the test liquid (the larger the chemical attack).

Preferably, the length L1 in the extending direction of the first stretchable wiring 21 is shorter than the length L2 in the extending direction of the second stretchable wiring 22. According to this configuration, also in a case where the first stretchable wiring 21 is harder than the second stretchable wiring 22, it is possible to suppress influence on elasticity of the stretchable device 1.

Preferably, Young's modulus (elastic modulus) of the first stretchable wiring 21 is larger than Young's modulus (elastic modulus) of the second stretchable wiring 22. According to this configuration, the first stretchable wiring 21 can be made harder than the second stretchable wiring 22. For this reason, hardness can be softened stepwise from an end portion of the electronic component 30 toward the second stretchable wiring 22. As a result, stress that may concentrate on the connection portion between the electronic component 30 and the first stretchable wiring 21 can be further reduced.

Preferably, the thickness t1 of the first stretchable wiring 21 is larger than the thickness t2 of the second stretchable wiring 22. According to this configuration, solder leaching resistance of the first stretchable wiring 21 can be further improved. Further, since the allowable stress σ1ₘₐₓ of the first stretchable wiring 21 can be increased, the first tensile load ratio can be further reduced. Further, since a clearance between the electronic component 30 and the stretchable substrate 11 can be increased, filling property of the covering layer 50 into the clearance can be enhanced.

Preferably, viscosity of a material of the first stretchable wiring 21 is larger than viscosity of a material of the second stretchable wiring 22. According to this configuration, the thickness t1 of the first stretchable wiring 21 can be made larger than the thickness t2 of the second stretchable wiring 22 more reliably.

Preferably, the first stretchable wiring 21 is made from a thermosetting material, the second stretchable wiring 22 is made from a thermoplastic material, and the first end portion 221 in the extending direction of the second stretchable wiring 22 is laminated on the second end portion 212 in the extending direction of the first stretchable wiring 21. According to this configuration, also in a case where stress is applied to the stretchable device 1, interfacial delamination between the first stretchable wiring 21 and the second stretchable wiring 22 can be suppressed, and mechanical strength of the stretchable device 1 can be further improved.

### Second Embodiment

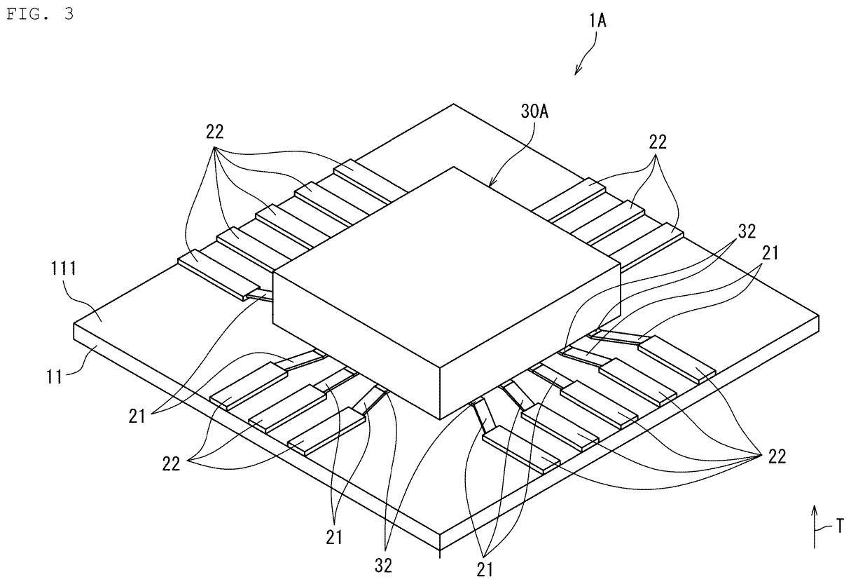

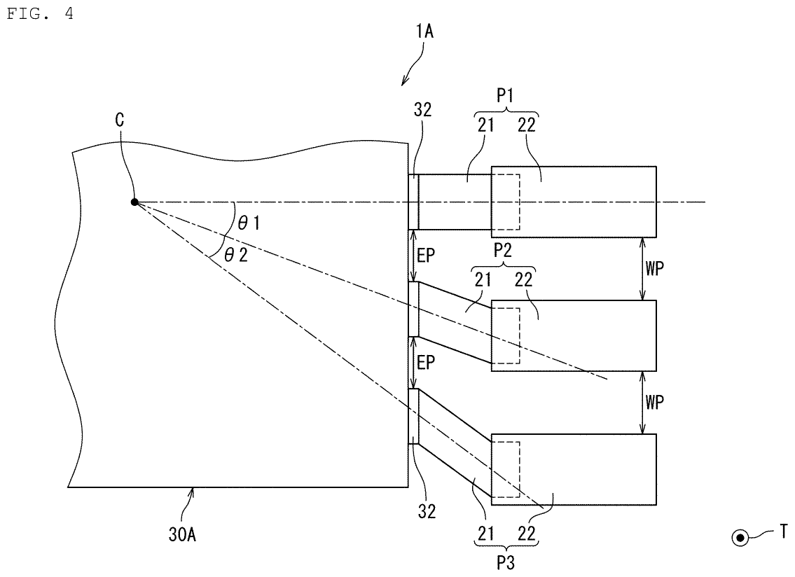

Hereinafter, a stretchable device 1A according to a second embodiment will be described with reference to FIGS. 3 and 4. FIG. 3 is a schematic perspective view of the stretchable device 1A. FIG. 4 is a schematic plan view illustrating a part of the stretchable device 1A. Specifically, FIG. 4 is a diagram of a lower right portion of FIG. 3 as viewed from above. The stretchable device 1A differs from the stretchable device 1 according to the first embodiment in configurations of an electronic component, a first stretchable wiring, and a second stretchable wiring.

As illustrated in FIGS. 3 and 4, in this embodiment, a shape of the electronic component 30A is a regular quadrangular prism. A plurality of external electrodes 32 are provided on an outer periphery of a lower surface of the electronic component 30A.

A plurality of the first stretchable wirings 21 and a plurality of the second stretchable wirings 22 exist, and there are a plurality of sets of stretchable wirings including the first stretchable wiring 21 connected to the electronic component 30A and the second stretchable wiring 22 connected to the first stretchable wiring 21. Specifically, one of the first stretchable wirings 21 is connected to one of the external electrodes 32 of the electronic component 30A, and one of the second stretchable wirings 22 is connected to the one of the first stretchable wirings 21. Then, a plurality of sets of stretchable wirings including the one of the first stretchable wirings 21 and the one of the second stretchable wirings 22 exist corresponding to the external electrodes 32.

According to the above configuration, since there are a plurality of sets of the stretchable wirings, stress that may concentrate on the connection portion between the electronic component 30A and the first stretchable wiring 21 can be further reduced, and mechanical strength of the stretchable device 1A can be further improved.

Preferably, when viewed from the direction (T direction) orthogonal to the main surface 111 of the stretchable substrate 11, each of the first stretchable wirings 21 in a plurality of sets of the stretchable wirings is arranged on an outer periphery of the electronic component 30A so as to be radial with respect to a center C of the electronic component 30A, and in two sets of stretchable wirings adjacent along an outer periphery of the electronic component 30A, an angle formed by an extending direction of the first stretchable wiring 21 in one set of stretchable wirings and an extending direction of the first stretchable wiring 21 in the other set of stretchable wirings is more than 0° and 90° or less.

Specifically, as illustrated in FIG. 4, the first stretchable wirings 21 in a set P1 of first stretchable wirings, a set P2 of second stretchable wirings, and a set P3 of third stretchable wirings are arranged on an outer periphery of the electronic component 30A so as to be radial with respect to the center C of the electronic component 30A. In the set P1 of first stretchable wirings and the set P2 of second stretchable wirings adjacent to each other along the outer periphery of the electronic component 30A, an angle θ1 formed by an extending direction of the first stretchable wiring 21 in the set P1 of first stretchable wirings and an extending direction of the first stretchable wiring 21 in the set P2 of second stretchable wirings is more than 0° and 90° or less. In the set P2 of second stretchable wirings and the set P3 of third stretchable wirings adjacent to each other along the outer periphery of the electronic component 30A, an angle θ2 formed by an extending direction of the first stretchable wiring 21 in the set P2 of second stretchable wirings and an extending direction of the first stretchable wiring 21 in the set P3 of third stretchable wirings is more than 0° and 90° or less.

Note that, in this embodiment, in a plurality of the second stretchable wirings 22 connected to the external electrode 32 provided on one side of an outer periphery of the electronic component 30A when viewed from the T direction, extending directions of the second stretchable wirings 22 are parallel to each other, but may be arranged inclined to each other.

According to the above configuration, since the first stretchable wirings 21 in a plurality of sets of the stretchable wirings are arranged on an outer periphery of the electronic component 30A so as to be radial with respect to the center C of the electronic component 30A, an inter-wiring pitch WP can be made different from an inter-electrode pitch EP. Further, a periphery of the electronic component 30A can be covered with the first stretchable wiring 21 softer than the electronic component 30A. For this reason, also in a case where tensile stress is applied to the stretchable device 1A, stress that may concentrate on the connection portion between the electronic component 30A and the first stretchable wiring 21 can be further reduced. Further, also in a case where tensile stress is applied to the stretchable device 1A from any direction, it is possible to reduce shear deformation of a most affected portion and to improve durability of the stretchable device 1A.

Note that each of the embodiments is exemplification, and the present disclosure is not limited to each of the embodiments. Further, each drawing illustrates exemplification of a constituent element, and does not limit a shape. Further, partial replacement or combination of configurations shown in different embodiments is possible.

In the above embodiment, there are a plurality of sets of the first stretchable wiring connected to the electronic component and the second stretchable wiring connected to the first stretchable wiring, but at least one set of the stretchable wirings are necessary.

### Example 1

Elongation with respect to stress was measured for the first stretchable wiring and the second stretchable wiring. FIG. 5 is a graph illustrating a relationship between elongation and stress of the first stretchable wiring and the second stretchable wiring. A graph G1 is a result in connection with the first stretchable wiring. A graph G2 is a result in connection with the second stretchable wiring.

As illustrated in FIG. 5, the first stretchable wiring was broken at elongation of about 78. Stress at this time was about 16 MPa. That is, allowable stress of the first stretchable wiring was about 16 MPa. The second stretchable wiring was broken at elongation of about 17%. Stress at this time was about 3 MPa. That is, allowable stress of the second stretchable wiring was about 3 MPa.

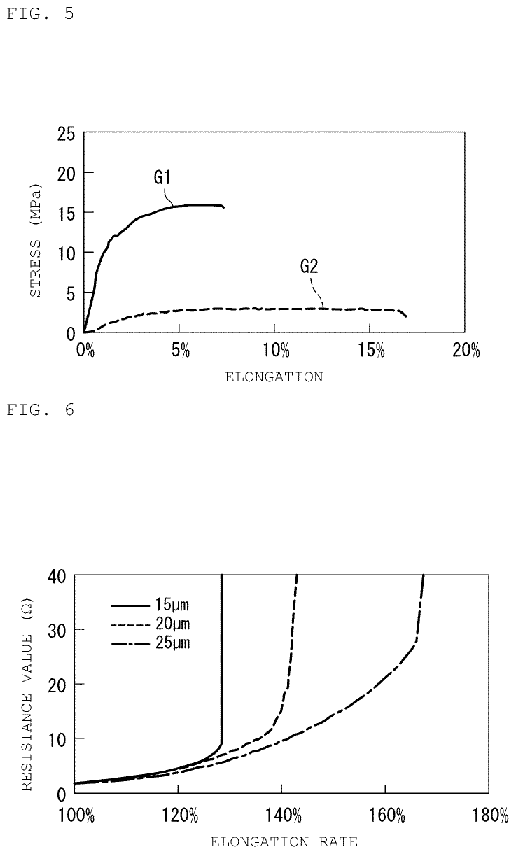

A relationship between thickness of the first stretchable wiring and an expansion and contraction rate until the first stretchable wiring is broken was measured. FIG. 6 is a graph illustrating thickness dependency of a relationship between an expansion and contraction rate and a resistance value of the first stretchable wiring.

As illustrated in FIG. 6, it has been found that an expansion and contraction rate until breakage increases as thickness of the first stretchable wiring increases. It is considered that as thickness of the first stretchable wiring increased, a tensile load acting on the first stretchable wiring decreased, and the first tensile load ratio decreased.

### Example 2

A range of the tensile load F within which the stretchable device can be used without breakage was calculated. Note that calculation below is an example, and a range of the tensile load F that can be used without breakage of the stretchable device may vary depending on a material and a shape of the stretchable substrate, a material and a shape of the first and second stretchable wirings, the number and arrangement of the electronic components, and the like.

In a case where an expansion and contraction rate is assumed to be ε%, the tensile load F that the stretchable device 1 can withstand without breakage is calculated by a formula below. The expansion and contraction rate ε can be defined as, for example, a ratio of the above-described displacement amount δ to a length of the entire stretchable substrate before expansion and contraction.

$$The tensile load F that the stretchable \\ \\ \\ device 1 can withstand without breakage = E \times ( ε / 100 ) \times S$$

E: Composite elastic modulus of the stretchable substrate 11, the first stretchable wiring 21, and the second stretchable wiring 22
S: Sectional area of the stretchable substrate 11 in a section orthogonal to the expansion and contraction direction

FIG. 7 is a schematic perspective view illustrating a part of a stretchable device 1B according to Example 2. As illustrated in FIG. 7, in the stretchable device 1B, a wiring and component group in which the second stretchable wiring 22, the first stretchable wiring 21, the electronic component 30, and the first stretchable wiring 21 are connected in this order is repeatedly connected along the A direction. Then, a plurality of the repeatedly connected wiring and component groups are present in a direction orthogonal to the A direction. In FIG. 7, the expansion and contraction direction is indicated by an arrow.

A broken line in a region AR of FIG. 7 indicates an imaginary line connecting midpoints between the electronic components 30 adjacent to each other. Note that, in FIG. 7, the region AR is drawn as a square, but the region AR is not necessarily a square. The center of gravity of the region AR overlaps the electronic component 30 when viewed from the T direction. An area of the region AR is a value obtained by dividing an area of the entire substrate by the number of the electronic components 30. When the region AR expands and contracts at an expansion and contraction rate of ε_{EX}, assuming that a composite elastic modulus of this occupied range is E_{EX} and a sectional area in a section orthogonal to the expansion and contraction direction is S_{EX}, a load dF in this occupied range is calculated by a formula below.

dF=E_{EX}×ε_{EX}×S_{EX}

An area of the region AR was assumed to be 10 mm², and the expansion and contraction rate ε_{EX} was assumed to be 20%. In the region AR, elastic modulus (Young's modulus), a sectional area in a section orthogonal to the expansion and contraction direction, a length in the expansion and contraction direction, and composite elastic modulus of the stretchable substrate, the first stretchable wiring, and the second stretchable wiring are shown in Table 1. The composite elastic modulus was estimated from elastic modulus, a sectional area, and a length of each member. As the stretchable substrate, thermoplastic polyurethane (TPU) was assumed. In FIG. 7, a length in the expansion and contraction direction of the first stretchable wiring 21 is a total value of a length L1a and a length L1b. A length in the expansion and contraction direction of the second stretchable wiring 22 is a total value of a length L2a and a length L2b. A length in the expansion and contraction direction of the stretchable substrate is a total value of the length L1a, the length L1b, the length L2a, and the length L2b.

TABLE 1

| | | | | | Composite |
|---|---|---|---|---|---|
| | Elastic | | | | elastic |
| | modulus | Sectional area | Length | | modulus |
| Stretchable | About 10 MPa | 10 mm × 40 μm | 10 | mm | About |
| substrate | | | | | 14 MPa |
| First | About 1 GPa | 400 μm × 20 μm | 2 | mm | |
| stretchable | | | | | |
| wiring | | | | | |
| Second | About 20 MPa | 400 μm × 20 μm | 8 | mm | |
| stretchable | | | | | |

wiring

When the sectional area S_{EX} is approximated to a sectional area of the stretchable substrate, the load dF is calculated as described below.

$$dF = {E}_{EX} \times {ε}_{EX} \times {S}_{EX} = 14 MPa \times 0.2 \times ( 4 \times {10}^{- 1} {mm}^{2} ) = 1.12 N$$

In a case where the entire area of the stretchable device 1B is 100 mm₂, a load is ten times as high, and the tensile load F that the stretchable device can withstand without breakage is calculated to be a maximum of 10 N.

### Example 3

Paste was used as a material of the first stretchable wiring, and a relationship between viscosity of the paste and thickness of the first stretchable wiring to be formed was investigated. Since a shape of the first stretchable wiring is an island shape, printing can be performed using a metal mask, and paste in which thixotropy, that is, viscosity of the paste, is increased by adding a thixotropic agent can be used. Paste was printed using a metal mask to form the first stretchable wiring.

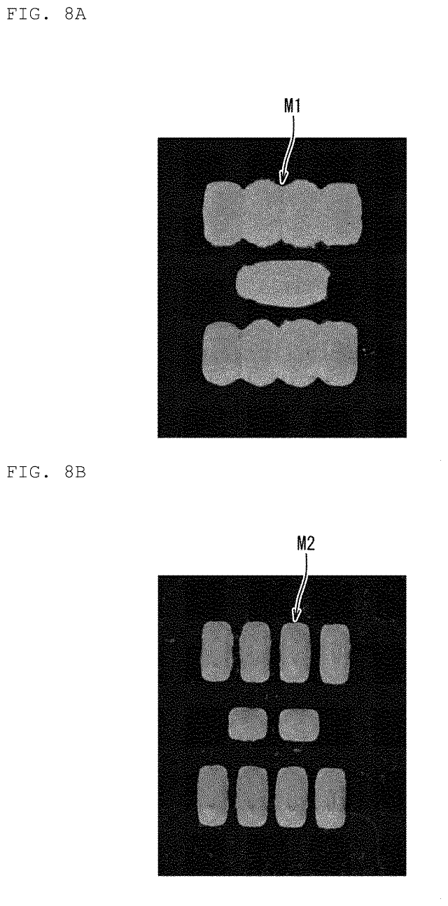

FIG. 8A is a diagram illustrating a coating shape of paste M1 to which a thixotropic agent is not added. FIG. 8B is a diagram illustrating a coating shape of paste M2 to which a thixotropic agent is added. As illustrated in FIG. 8A, regarding the paste M1 to which a thixotropic agent was not added, the paste spread, and thickness was about 25 μm. As illustrated in FIG. 8B, regarding the paste M2 to which a thixotropic agent was added, the paste did not spread, and thickness was about 50 μm. It was found that thickness of the first stretchable wiring can be increased with the paste M2 in which viscosity is increased by adding a thixotropic agent.

Further, a sample in which thickness of the first stretchable wiring was 10 μm and a sample in which thickness of the first stretchable wiring was 50 μm were prepared. Then, for each sample, thickness of solder and the number of times of reflowing were variously changed to evaluate solder leaching resistance. Thickness of the solder was changed to 20 μm, 50 μm, 80 μm, 110 μm, and 140 μm. The number of times of reflowing was changed to one time, two times, three times, four times, and five times. In a sample in which thickness of the first stretchable wiring was 10 μm, solder leaching was observed, but in a sample in which thickness of the first stretchable wiring was 50 μm, solder leaching was not observed. It was found that solder leaching resistance is improved by increasing thickness of the first stretchable wiring.

### Example 4

A relationship between lamination order of the first stretchable wiring and the second stretchable wiring and interfacial delamination was investigated. Specifically, it was investigated whether behavior in which interfacial delamination occurs is different between a case where a first end portion of the second stretchable wiring is laminated on a second end portion of the first stretchable wiring as illustrated in FIG. 2 and a case where the second end portion of the first stretchable wiring is laminated on the first end portion of the second stretchable wiring. As a material of the first stretchable wiring, a thermosetting material was used. As a material of the second stretchable wiring, a thermoplastic material was used. Table 2 shows a result when the first end portion of the second stretchable wiring was laminated on the second end portion of the first stretchable wiring. Table 3 shows a result when the second end portion of the first stretchable wiring was laminated on the first end portion of the second stretchable wiring. In Tables 2 and 3, for example, a numerical value described as “0.16 N/mm” means a tensile load per unit width at the time of interfacial delamination.

TABLE 2

| | | | Upper layer: | |
|---|---|---|---|---|
| | Curing | | second stretchable wiring | |
| | temperature | | 80° C. | 140° C. |
| Lower layer: | 80° | C. | Cohesive failure | Cohesive failure |
| first | | | 0.16 N/mm | 0.14 N/mm |
| stretchable | 140° | C. | Cohesive failure | Cohesive failure |

| | | |
|---|---|---|
| wiring | 0.30 N/mm | 0.41 N/mm |

TABLE 3

| | Upper layer: |
|---|---|
| Curing | first stretchable wiring |

| | temperature | | 80° C. | 140° C. |
|---|---|---|---|---|
| Lower layer: | 80° | C. | Interfacial | Interfacial |
| second | | | delamination | delamination |
| stretchable | | | 0.19 N/mm | 0.03 N/mm |
| wiring | 140° | C. | Interfacial | Interfacial |

| | |
|---|---|
| delamination | delamination |
| 0.08 N/mm | 0.05 N/mm |

As shown in Tables 2 and 3, when a thermosetting material was used as a material of the first stretchable wiring and a thermoplastic material was used as a material of the second stretchable wiring, a cohesive failure occurred in a case where the first end portion of the second stretchable wiring was laminated on the second end portion of the first stretchable wiring, and interfacial delamination occurred when the second end portion of the first stretchable wiring was laminated on the first end portion of the second stretchable wiring. The cohesive failure is not a state in which an interface between the first stretchable wiring and the second stretchable wiring is delaminated, but a state in which a failure occurs inside any of the first stretchable wiring and the second stretchable wiring. It has been found that when a thermosetting material is used as a material of the first stretchable wiring and a thermoplastic material is used as a material of the second stretchable wiring, interfacial delamination is suppressed and mechanical strength is improved when the first end portion of the second stretchable wiring is laminated on the second end portion of the first stretchable wiring.

The present disclosure includes an aspect below.

<1> A stretchable device including: a stretchable substrate having a main surface; an electronic component on the main surface of the stretchable substrate; a first stretchable wiring connected to the electronic component; and a second stretchable wiring connected to the first stretchable wiring, in which a first end portion in an extending direction of the first stretchable wiring is connected to the electronic component, and a second end portion in the extending direction of the first stretchable wiring is connected to a third end portion in the extending direction of the second stretchable wiring.

<2> The stretchable device according to <1> that satisfies the following: σ1≤an allowable stress of the first stretchable wiring, and σ2≤an allowable stress of the second stretchable wiring, where σ1=(δ×E1×S2×E2)/(L1×S2×E2+L2×S1×E1), σ2=(δ×E1×S1×E2)/(L2×S1×E1+L1×S2×E2), δ: overall displacement amount of the first stretchable wiring and the second stretchable wiring, L1: length of the first stretchable wiring in an expansion and contraction direction, L2: length of the second stretchable wiring in an expansion and contraction direction, S1: sectional area of the first stretchable wiring in a section orthogonal to the expansion and contraction direction, S2: sectional area of the second stretchable wiring in the section orthogonal to the expansion and contraction direction, E1: elastic modulus of the first stretchable wiring, and E2: elastic modulus of the second stretchable wiring.

<3> The stretchable device according to <2> that further satisfies the following: σ1≤0.80×the allowable stress of the first stretchable wiring, and σ2≤0.80×the allowable stress of the second stretchable wiring.

<4> The stretchable device according to <2> that further satisfies the following: σ1≤0.50×the allowable stress of the first stretchable wiring, and σ2≤0.50×the allowable stress of the second stretchable wiring.

<5> The stretchable device according to any one of <1> to <4>, further including a connection member that connects the electronic component and the first stretchable wiring, in which the connection member does not overlap the third end portion in the extending direction of the second stretchable wiring when viewed from a direction orthogonal to the main surface of the stretchable substrate.

<6> The stretchable device according to any one of <1> to <5>, in which the first stretchable wiring is one of a plurality of first stretchable wirings and the second stretchable wiring is one of a plurality of second stretchable wirings, and a plurality of sets of stretchable wirings each comprising the first stretchable wiring connected to the electronic component and the second stretchable wiring connected to the first stretchable wiring, respectively.

<7> The stretchable device according to <6>, in which each of the first stretchable wirings in the plurality of sets of stretchable wirings are arranged on an outer periphery of the electronic component so as to be radial with respect to a center of the electronic component when viewed from a direction orthogonal to the main surface of the stretchable substrate, and in two sets of the stretchable wirings that are adjacent to each other along the outer periphery of the electronic component among the plurality of sets of stretchable wirings, an angle formed by the extending direction of the first stretchable wiring in a first set of the stretchable wirings and the extending direction of the first stretchable wiring in a second set of the stretchable wirings is more than 0° and 90° or less.

<8> The stretchable device according to any one of <1> to <7>, in which solder leaching resistance of the first stretchable wiring is higher than solder leaching resistance of the second stretchable wiring.

<9> The stretchable device according to any one of <1> to <8>, in which a solubility in resin of the first stretchable wiring is smaller than a solubility in resin of the second stretchable wiring.

<10> The stretchable device according to any one of <1> to <9>, in which a length in the extending direction of the first stretchable wiring is shorter than a length in the extending direction of the second stretchable wiring.

<11> The stretchable device according to any one of <1> to <10>, in which a Young's modulus of the first stretchable wiring is larger than a Young's modulus of the second stretchable wiring.

<12> The stretchable device according to any one of <1> to <11>, in which a thickness of the first stretchable wiring is larger than a thickness of the second stretchable wiring.

<13> The stretchable device according to any one of <1> to <12>, in which a viscosity of a material of the first stretchable wiring is larger than a viscosity of a material of the second stretchable wiring.

<14> The stretchable device according to any one of <1> to <13>, in which the first stretchable wiring is made from a thermosetting material, the second stretchable wiring is made from a thermoplastic material, and the third end portion in the extending direction of the second stretchable wiring is laminated on the second end portion in the extending direction of the first stretchable wiring.

### DESCRIPTION OF REFERENCE SYMBOLS

1, 1A, 1B: Stretchable device
11: Stretchable substrate
111: Main surface
21: First stretchable wiring
211: First end portion of first stretchable wiring
212: Second end portion of first stretchable wiring
22: Second stretchable wiring
221: First end portion of second stretchable wiring
222: Second end portion of second stretchable wiring
30, 30A: Electronic component
31, 32: External electrode
40: Connection member
50: Covering layer
C: Center
L1: Length of first stretchable wiring
L2: Length of second stretchable wiring
P1, P2, P3: Set of stretchable wirings
t1: Thickness of first stretchable wiring
t2: Thickness of second stretchable wiring
W1: Width of first stretchable wiring
W2: Width of second stretchable wiring

1. A stretchable device comprising:
a stretchable substrate having a main surface;
an electronic component on the main surface of the stretchable substrate;
a first stretchable wiring connected to the electronic component; and
a second stretchable wiring connected to the first stretchable wiring,
wherein a first end portion in an extending direction of the first stretchable wiring is connected to the electronic component, and
a second end portion in the extending direction of the first stretchable wiring is connected to a third end portion in the extending direction of the second stretchable wiring.

2. The stretchable device according to claim 1, wherein:
σ1≤an allowable stress of the first stretchable wiring, and
σ2≤an allowable stress of the second stretchable wiring,
where
$$σ 1 = ( δ \times E 1 \times S 2 \times E 2 ) / ( L 1 \times S 2 \times E 2 + L 2 \times S 1 \times E 1 ) , \\ σ 2 = ( δ \times E 1 \times S 1 \times E 2 ) / ( L 2 \times S 1 \times E 1 + L 1 \times S 2 \times E 2 ) ,$$
δ: overall displacement amount of the first stretchable wiring and the second stretchable wiring,
L1: length of the first stretchable wiring in an expansion and contraction direction,
L2: length of the second stretchable wiring in an expansion and contraction direction,
S1: sectional area of the first stretchable wiring in a section orthogonal to the expansion and contraction direction,
S2: sectional area of the second stretchable wiring in the section orthogonal to the expansion and contraction direction,
E1: elastic modulus of the first stretchable wiring, and
E2: elastic modulus of the second stretchable wiring.

3. The stretchable device according to claim 2, wherein:
$$σ 1 \leq 0.8 \times the allowable stress of the first stretchable wiring , and \\ σ 2 \leq 0.8 \times the allowable stress of the second stretchable wiring .$$

4. The stretchable device according to claim 2, wherein:
$$σ 1 \leq 0.5 \times the allowable stress of the first stretchable wiring , and \\ σ 2 \leq 0.5 \times the allowable stress of the second stretchable wiring .$$

5. The stretchable device according to claim 1, further comprising:
a connection member that connects the electronic component and the first stretchable wiring,
wherein the connection member does not overlap the third end portion in the extending direction of the second stretchable wiring when viewed from a direction orthogonal to the main surface of the stretchable substrate.

6. The stretchable device according to claim 1, wherein
the first stretchable wiring is one of a plurality of first stretchable wirings and the second stretchable wiring is one of a plurality of second stretchable wirings, and
a plurality of sets of stretchable wirings each comprising the first stretchable wiring connected to the electronic component and the second stretchable wiring connected to the first stretchable wiring, respectively.

7. The stretchable device according to claim 6, wherein each of the first stretchable wirings in the plurality of sets of stretchable wirings are arranged on an outer periphery of the electronic component so as to be radial with respect to a center of the electronic component when viewed from a direction orthogonal to the main surface of the stretchable substrate.

8. The stretchable device according to claim 7, wherein in two sets of the stretchable wirings that are adjacent to each other along the outer periphery of the electronic component among the plurality of sets of stretchable wirings, an angle formed by the extending direction of the first stretchable wiring in a first set of the stretchable wirings and the extending direction of the first stretchable wiring in a second set of the stretchable wirings is more than 0° and 90° or less.

9. The stretchable device according to claim 1, wherein a solder leaching resistance of the first stretchable wiring is higher than a solder leaching resistance of the second stretchable wiring.

10. The stretchable device according to claim 1, wherein a solubility in resin of the first stretchable wiring is smaller than a solubility in resin of the second stretchable wiring.

11. The stretchable device according to claim 1, wherein a length in the extending direction of the first stretchable wiring is shorter than a length in the extending direction of the second stretchable wiring.

12. The stretchable device according to claim 1, wherein a Young's modulus of the first stretchable wiring is larger than a Young's modulus of the second stretchable wiring.

13. The stretchable device according to claim 1, wherein a thickness of the first stretchable wiring is larger than a thickness of the second stretchable wiring.

14. The stretchable device according to claim 1, wherein a viscosity of a material of the first stretchable wiring is larger than a viscosity of a material of the second stretchable wiring.

15. The stretchable device according to claim 1, wherein
the first stretchable wiring is made from a thermosetting material, and
the second stretchable wiring is made from a thermoplastic material.

16. The stretchable device according to claim 15, wherein the third end portion in the extending direction of the second stretchable wiring is laminated on the second end portion in the extending direction of the first stretchable wiring.

17. The stretchable device according to claim 1, further comprising a covering layer that covers the first stretchable wiring and the second stretchable wiring.
